(19) United States
(12) Patent Application Publication
(10) Pub. No.: US 2009/0303770 A1
(43) Pub. Date: Dec. 10, 2009

(54) Memory chip and semiconductor device

(75) Inventor: Kayoko Shibata, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: ELPIDA MEMORY, INC., Tokyo (JP)

(21) Appl. No.: 12/457,204

(22) Filed: Jun. 3, 2009

(30) Foreign Application Priority Data
Jun. 4, 2008 (JP) 2008-147008

(51) Int. Cl. G11C 5/06; G11C 7/10

(52) U.S. Cl. 365/63; 365/189.03

(57) ABSTRACT

A memory chip is provided, including internal signal/data terminals disposed in a central part of the memory chip and memory cell arrays arranged around the internal terminals to surround the same and electrically connected thereto. A semiconductor device is also provided, having a memory chip and a logic chip stacked with an interposer interposed therebetween. The logic chip has internal signal/data terminals disposed in its central part and electrically connected to the memory chip. The memory chip includes internal signal/data terminals disposed in its central part, and memory arrays arranged around the internal terminals to surround the same and connected thereto. The internal terminals of the logic chip are connected to the internal terminals of the memory chip via through holes (through electrodes) in the interposer.

This application is based upon and claims the benefit of priority from Japanese patent application No. 2008-147008, filed on Jun. 4, 2008, the disclosure of which is incorporated herein in its entirety by reference.

### BACKGROUND OF THE INVENTION

1. Field of the Invention

This invention relates to a semiconductor device and, particularly, to a memory chip layout and a semiconductor device having a structure in which a memory chip and a logic chip are stacked with an interposer interposed therebetween.

2. Description of the Related Art

In recent years, development of a variety of semiconductor devices, in which a memory chip and a logic chip are connected, has been increasing. These semiconductor devices are required to have increased capacity, reduced package size, and increased operation speed. In order to meet these requirements, a technique is proposed to stack a singularity or plurality of memory chips and logic chips (for example, in Japanese Laid-Open Patent Publication No. 2006-12358 (Patent Document 1)).

According to Patent Document 1, the technique to stack a plurality of chips is carried out by providing a through electrode passing through the chips to establish electrical connection between the chips.

FIG. 13 is a diagram schematically showing a functional configuration of a conventional stacked semiconductor device having a memory chip and a logic chip. FIG. 13 particularly shows a state where a memory chip 200 is disposed on the upper side and a logic chip 300 is disposed on the lower side.

The memory chip 200 used herein is provided therein principally with memory cells, a circuit for selecting memory cells, a circuit for holding data in the memory cells, a command decoder for controlling operation of the memory chips, and minimum required circuits for detecting defective products in a memory chip wafer test.

The logic chip is provided therein with a first-stage circuit 310 for receiving input signals and data signals necessary for the memory chip through external terminals, and interface circuits for controlling the input/output timing or frequency of data written to or read from the memory cell (e.g. a latch circuit 312, a DLL (Delayed Locked Loop) 313, and an input/output buffer 314).

Transistors for use in the logic chip, which are manufactured by the logic process, are operable at a higher speed than transistors manufactured by the memory process. Therefore, the requirement of increasing the operation speed is satisfied by providing the interface circuits in the logic chip.

The logic chip may be provided with, in addition to the above-mentioned circuits, circuits for processing data input to or output from the memory chip on a system, such as an image processing circuit or a circuit for controlling a controller such as a PC. In this case, not only the increase of operation speed but also the size reduction of the system as a whole can be realized.

The circuits on the memory chip shown in FIG. 13 are an example of minimum required circuits. The allotment of the circuits to between the memory chip and the logic chip is not limited to the one shown in FIG. 13, but may be done in various manners.

In a logic chip to be used together with such a memory chip, internal pads to be connected to external terminals are usually disposed around the outer periphery of the chip as shown in FIG. 2. Internal signal terminals to connect between the memory chip and the logic chip are disposed in a central part of the logic chip in view of operating performance and ease of layout.

On the other hand, internal terminals of conventional memory chips are disposed over the entire transverse or vertical dimension on the memory chip. Specifically, examples of these internal terminals are shown in FIG. 14A in which three memory arrays are arranged in a vertical direction while three memory arrays are arranged in a transverse direction, and in FIG. 14B in which four memory arrays are arranged in the upper row while four memory arrays are arranged in the lower row. A read data amplifier and a write data amplifier (collectively referred to as the data amplifiers) are typically disposed between the memory arrays to extend across the memory chip. Since the internal terminals are to be disposed adjacent to the data amplifiers, they are located at the positions indicated as “internal terminal” in FIGS. 14A and 14B.

When a memory chip configured in this manner is stacked on the logic chip as shown in FIG. 2 with an interposer interposed therebetween, a structure as shown in FIG. 15 is obtained. The memory chip 200 and the logic chip 300 are connected by way of rewiring lines and through holes (through electrodes) provided in the interposer chip 400.

### SUMMARY

A problem arises here that the rewiring lines in the interposer for connecting the internal signal terminals located near the outer periphery of the memory chip overlap with the rewiring lines in the interposer connected to the internal terminals located at a central part of the logic chip, resulting in complicated configuration of the rewiring lines.

When a large number of data lines are required (for example, when there are 256 or 512 signals to be connected between the memory chip and the logic chip), in particular, the rewiring line configuration must be as simple as possible.

In a conventional memory chip, as described above, internal terminals are disposed on the memory chip to extend over the entire transverse or vertical dimension of the memory chip. Therefore, when such a memory chip is connected to a logic chip with an interposer interposed therebetween, the configuration of connection lines becomes complicated.

The present invention provides a memory chip with a novel layout design capable of solving the problems described above.

This invention provides a semiconductor device formed by stacking a memory chip having the novel layout design and a logic chip.

In accordance with an aspect of this invention, there is provided a memory chip having internal signal/data terminals disposed in a central part of the memory chip, and memory cell arrays arranged around the internal terminals to surround the same and electrically connected to the internal terminals.

In another aspect of this invention, there is obtained a semiconductor device comprising a memory chip and a logic chip stacked with an interposer interposed therebetween, wherein the logic chip has internal signal/data terminals disposed in its central part and electrically connected to the memory chip, the memory chip includes internal signal/data terminals disposed in its central part and memory arrays arranged around the internal terminals to surround the same and connected to the internal terminals, and the internal terminals of the logic chip are connected to the internal terminals of the memory chip via through holes in the interposer.

According to this invention, the internal terminals for electrically connecting the memory chip to the logic chip are disposed in a central part of the memory chip, and hence the memory chip can be connected to the logic chip without the need of complicated connections.

### BRIEF DESCRIPTION OF THE DRAWINGS

FIG. 1A is a plan view showing a memory chip layout according to first to third embodiments of this invention;

FIG. 1B is a plan view showing a memory chip layout according to a fourth embodiment of this invention;

FIG. 2 is a plan view showing a logic chip layout used in this invention;

FIG. 3 is a cross-sectional view schematically showing a stacked semiconductor device according to a fifth embodiment of this invention;

FIG. 4 is a diagram showing a layout of a bank pair AB used in a first embodiment of this invention;

FIG. 5 is a diagram showing a layout of a bank pair CD used in the first embodiment of this invention;

FIG. 6 is a diagram showing a layout of a bank pair AB used in a second embodiment of this invention;

FIG. 7 is a diagram showing a layout of a bank pair CD used in the second embodiment of this invention;

FIG. 8 is a diagram showing a layout of a bank pair AB used in a third embodiment of this invention;

FIG. 9 is a diagram showing a layout of a bank pair CD used in the third embodiment of this invention;

FIG. 10 is a plan view showing a detailed portion of a cell block of a bank A shown in FIG. 4;

FIG. 11 is a cross-sectional view schematically showing wiring lines in a memory chip according to the third embodiment of this invention;

FIG. 12 is a timing chart for explaining operation of the third embodiment of this invention;

FIG. 13 is a functional block diagram showing a conventional stacked semiconductor structure;

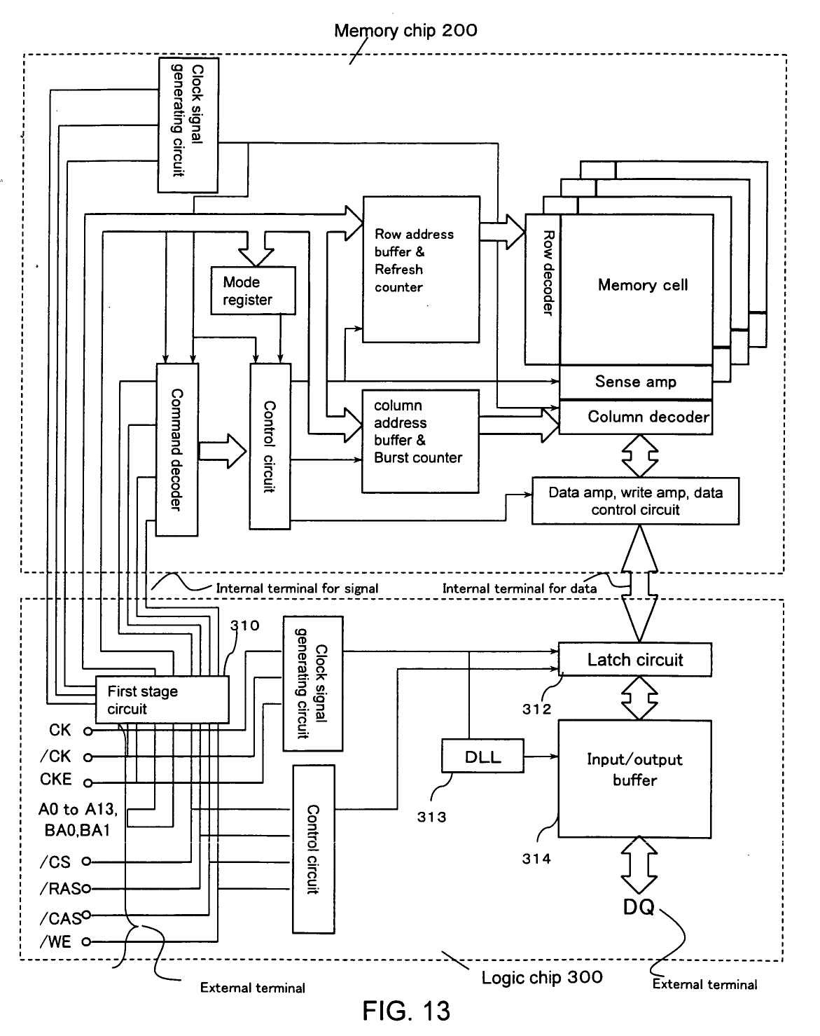

FIG. 14A is a plan view showing a layout of a conventional memory chip;

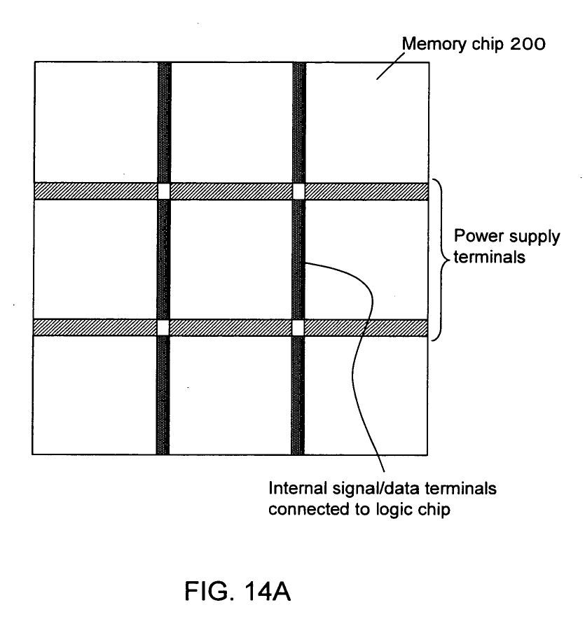

FIG. 14B is a plan view showing another layout of a conventional memory chip; and

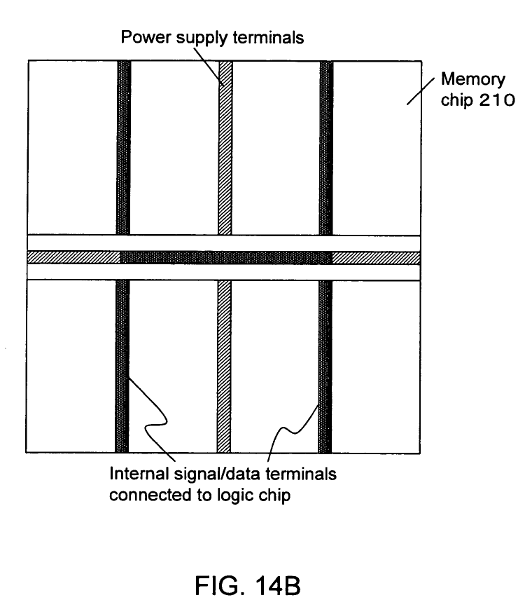

FIG. 15 is a cross-sectional view schematically showing a conventional stacked semiconductor device.

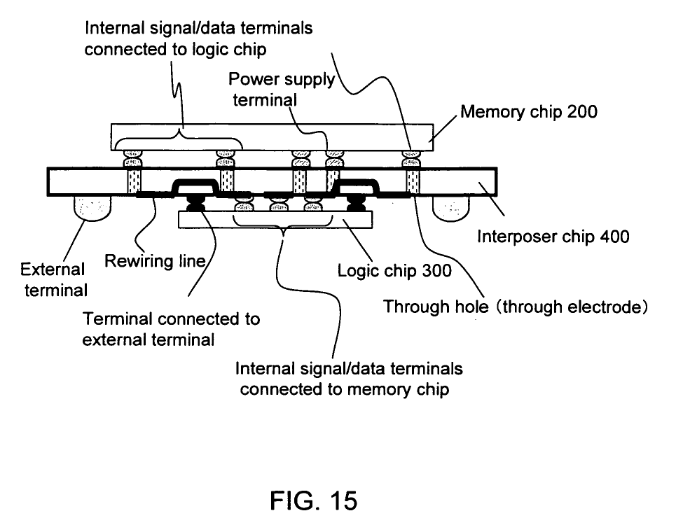

### DETAILED DESCRIPTION OF EXEMPLARY EMBODIMENTS

According to an embodiment of this invention, a memory chip has internal signal/data terminals disposed in a central part of the memory chip, and memory cell arrays arranged around the internal terminals to surround the same and electrically connected to the internal terminals, and the internal terminals are arranged to form four sides of a substantially rectangular shape in the central part of the memory chip.

In a preferred embodiment of the invention, the arrangement of the internal terminals includes a first row of internal terminals defining one side of the substantially rectangular shape extending in a first direction (row direction), and a second row of internal terminals adjacent to the first row of internal terminals and defining one side of the substantially rectangular shape extending in a second direction (column direction) orthogonal to the first direction.

The memory cell arrays include a first pair of memory cell arrays consisting of a first memory cell array adjacent to the first row of internal terminals in the first direction, and a second memory cell array adjacent to the first memory cell array in the second direction, and a second pair of memory cell arrays consisting of a third memory cell array adjacent to the second row of internal terminals in the second direction, and a fourth memory cell array adjacent to the third memory cell array in the first direction. The second memory cell array and the third memory cell array are adjacent to each other in the first direction. The first pair of memory cell arrays has a data amplifier between the first pair of memory cell arrays and the first row of internal terminals, and the second pair of memory cell arrays has a data amplifier between the second pair of memory cell arrays and the second row of internal terminals.

The memory chip includes a third pair of memory cell arrays arranged point-symmetrically to the first pair of memory cell arrays with respect to the center of the memory chip layout and having the same configuration as that of the first memory cell array.

The memory chip includes a fourth pair of memory cell arrays arranged point-symmetrically to the second pair of memory cell arrays with respect to the center of the memory chip layout and having the same configuration as that of the second pair of memory cell arrays.

More specifically, the first memory cell array and the second memory cell array each have a local IO line to which a digit line selected by a column select line is connected via a first transfer unit and a main IO line laid in the column direction (second direction) and to which the local IO line is connected via a second transfer unit.

In a preferred embodiment, a second main IO line is further provided for connecting the main IO line of the first memory cell array to the main IO line of the second memory cell array via a third transfer unit, and the main IO line of the first memory cell array is used in common by the first memory cell array and the second memory cell array to input and output data.

The third memory cell array and the fourth memory cell array each have a local IO line to which a digit line selected by a column select line is connected via a first transfer unit, a main IO line laid in the column direction (first direction) and to which the local IO line is connected via a second transfer unit, and a second main IO line laid in the row direction (second direction) and connected to the main IO lines

The main IO line of the third memory cell array and the main IO line of the fourth memory cell array are connected to each other via a third transfer unit, and the main IO line of the third memory cell array is used in common by the third memory cell array and the fourth memory cell array to input and output data.

The internal terminals may be arranged to form a substantially rectangular shape in a central part of the memory chip.

In this case, the arrangement of the internal terminals desirably includes first to fourth row of internal terminals arranged in matrix. The memory cell arrays include a first pair of memory cell arrays including a first memory cell array located adjacent to the first row of internal terminals in a first direction and a second memory cell array located adjacent to the first memory cell array in a second direction orthogonal to the first direction, a second pair of memory cell arrays arranged point-symmetrically to the first pair of memory cell arrays with respect to the center of the memory cell layout and having the same configuration as the first pair of memory cell arrays, a third pair of memory cell arrays arranged symmetrically to the first pair of memory cell arrays with respect to the center line extending in the first direction passing the center of the layout, and having the same configuration as the first pair of memory cell arrays, and a fourth pair of memory cell arrays arranged symmetrically to the first pair of memory cell arrays with respect to the center line extending in the second direction passing the center of the layout, and having the same configuration as the first pair of memory cell arrays. The first to fourth pairs of memory cell arrays each have a data amplifier between the first to fourth pairs of memory cell arrays and the arrangement of the internal terminals.

Preferred exemplary embodiments of this invention will be described with reference to the accompanying drawings.

### First Exemplary Embodiment

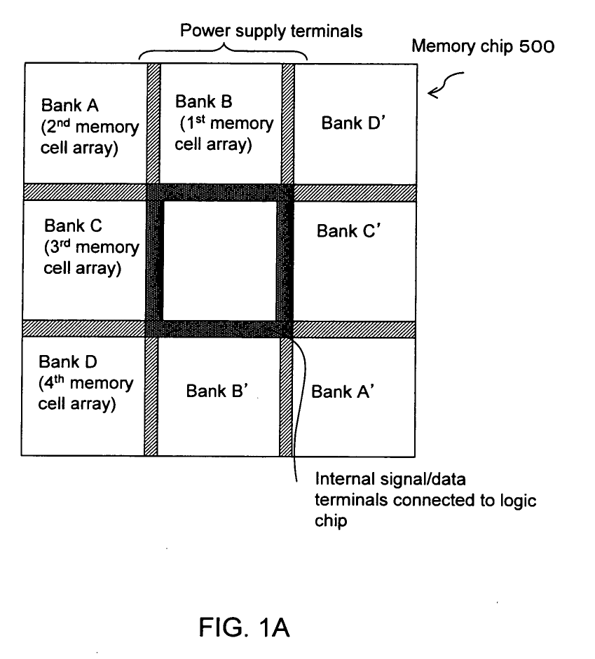

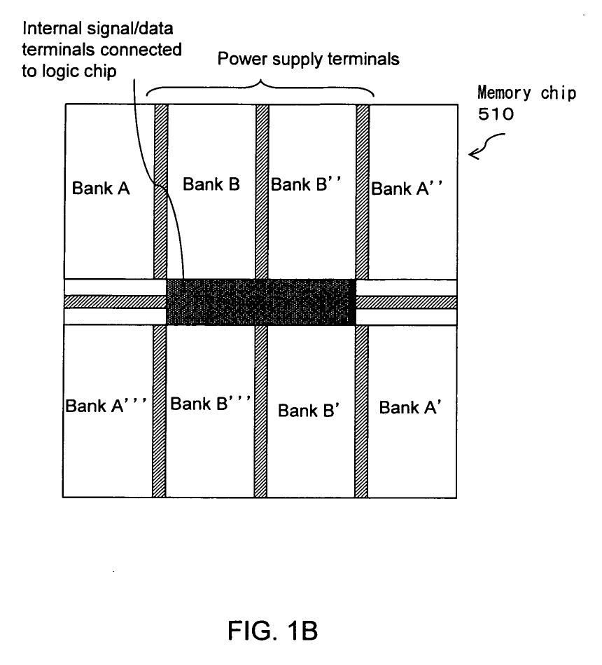

FIG. 1A is a plan view showing a layout of a memory chip according to a first embodiment of this invention. In this layout, internal signal/data terminals are disposed in a central part of the memory chip. In FIG. 1A, a rectangular region is formed in the central part, and each of the four sides of this rectangular region corresponds to an internal terminal region. A plurality of banks are arranged to surround these internal terminal regions. In this embodiment, each two of the banks form a bank pair. Each bank pair is positioned such that the internal terminals thereof are located in the internal terminal region in the central part. On the other hand, power supply terminals are disposed to extend from the central part to the periphery of the memory chip. It is desirable that the internal terminal region of the memory chip is located inside the region of those terminals to be connected to external terminals provided on a logic chip. This is for the purpose of avoiding complicating the rewiring structure of the interposer when the memory and logic chips are stacked and connected to each other.

Describing more specifically, a bank A and a bank B include a second memory cell array and a first memory cell array, respectively, and internal terminals of the bank pair of the banks A and B are located in the upper side of the internal terminal region in the central part of the memory chip. Banks C and D include a third memory cell array and a fourth memory cell array, respectively, and the internal terminals of the bank pair of the banks C and D are located in the left side of the internal terminal region in the central part. Likewise, the internal terminals of a bank pair of banks A′ and B′ are located in the lower side of the internal terminal region in the central part, and the internal terminals of a bank pair of banks C′ and D′ are located in the right side of the internal terminal region in the central part. As described later on, the bank pairs are arranged in such directions that row select lines and column select lines are laid in common directions among the bank pairs.

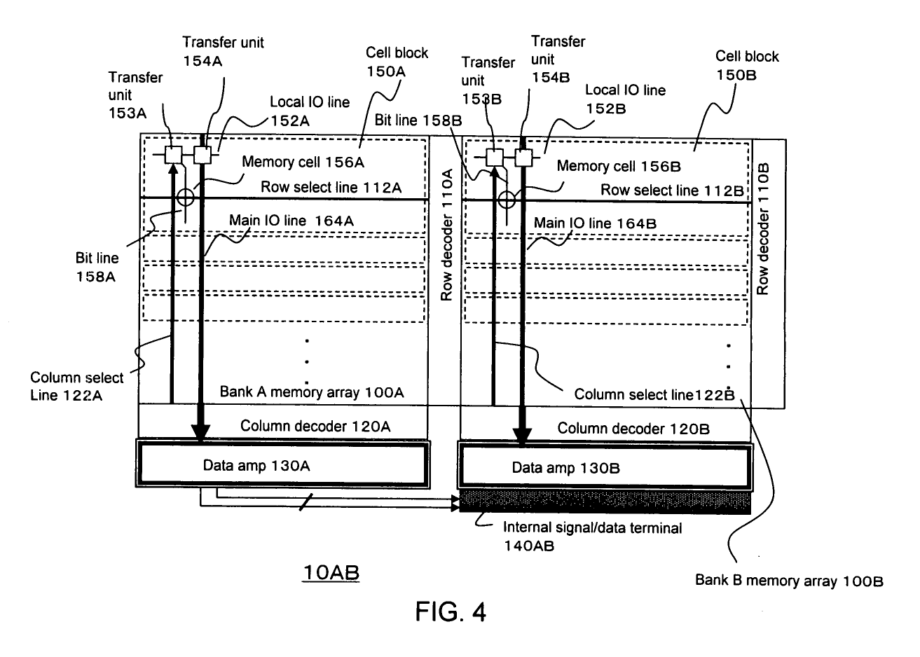

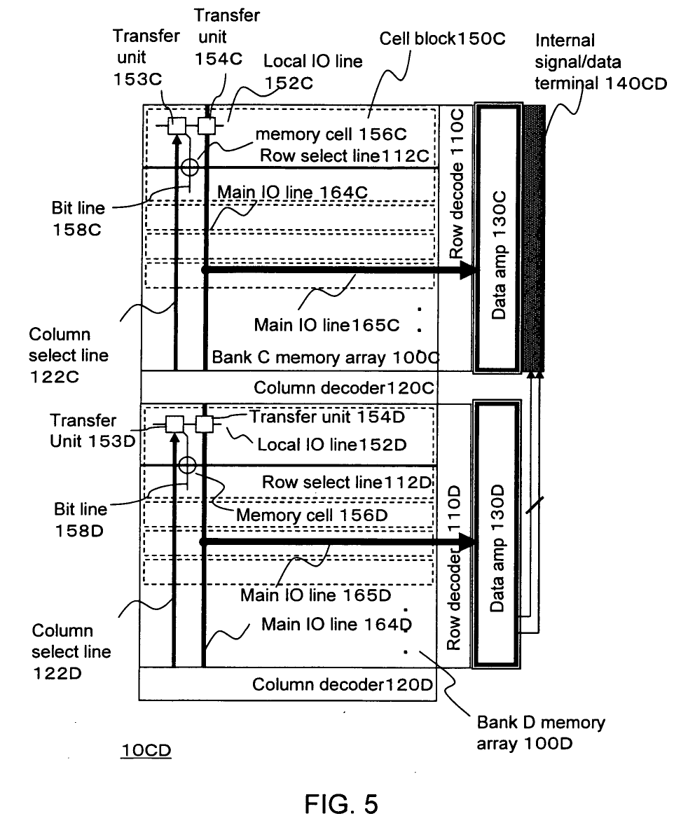

Referring to FIGS. 4 and 5, description will be made of layouts of bank pairs for realizing the memory chip of this invention.

A bank pair shown in FIG. 4 consists of a bank A and a bank B. The bank A includes a second memory array (bank A memory array) 100A, a plurality of row select lines 112A, a plurality of bit lines 158A, and a plurality of column select lines 122A. The bank B includes a first memory array (bank B memory array) 100B, a plurality of row select lines 112B, a plurality of bit lines 158B, and a plurality of column select lines 122B.

The bank B will be described further. A row decoder 110B is disposed on the right-hand side of the bank B memory array 100B and a column decoder 120B is disposed on the lower side thereof. A column select line 122B is provided to extend from the column decoder in association with each of the bit lines so that a column select signal is supplied to a transfer unit 153B. A transfer unit 153B is provided in association with each of the bit lines so that the transfer unit 153B amplifies a signal on the associated bit line, and connects or disconnects the bit line to a local IO line 152B. Each of the local IO line 152B is further provided with a transfer unit 154B to open and close the connection between the local IO line 152B and a main IO line 164B. The transfer units 153B and 154B may be formed by a transfer gate or an amplifier circuit. The main IO line 164B is connected to one of data amplifiers 130B provided under the column decoder 120B. A data amplifier is composed of a buffer circuit for amplifying input data and a buffer circuit for amplifying output data. Input and output of the data amplifier 130B are connected to one of internal terminals 140AB below the bank B.

Since the bank A has the same configuration as that of the bank B, components of the bank A equivalent to those of bank B are identified by the same reference numerals but with the post script B being replaced with A, and detailed description thereof will be omitted.

The bank A is different from the bank B in the following points. There is no internal signal terminal provided below the bank A, and the bank A is connected to the internal terminal 140AB below the bank B through a data bus running outside the data amplifier 130A, parallel to the direction along which the amplifiers are arranged. This configuration of the bank pair is suitable when the number of IO lines is relatively small.

A memory array of each bank consists of a plurality of cell blocks 150A (150B). As for the memory array of the bank A, each region enclosed by the broken lines in FIG. 4 represents a cell block 150A. Thus, the plurality of cell blocks are arranged adjacent to each other as shown in FIG. 4. While the configuration of only the uppermost cell block is illustrated in FIG. 4, the other cell blocks also have the same configuration.

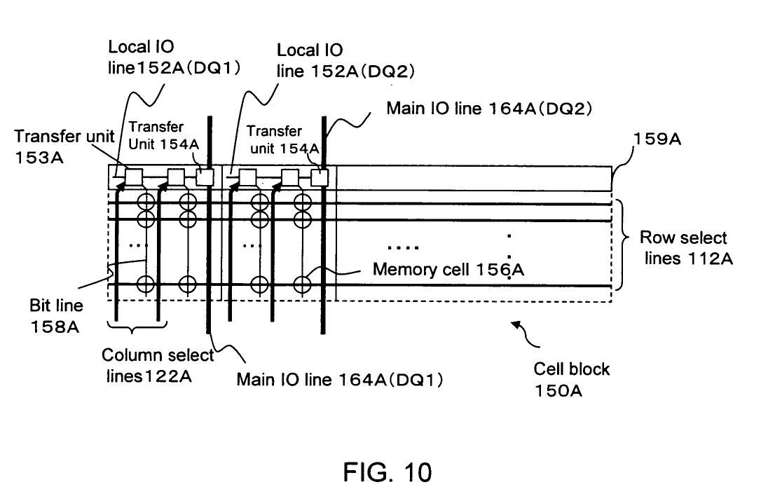

Referring to FIG. 10, the cell blocks will be described in detail.

The cell block 150A includes memory cells arranged in matrix, row select lines 112A for selecting a row of the memory cells, bit lines 158A arranged in a column direction of the memory cells, column select lines 122A arranged parallel with the bit lines, and an array circuit region 159A. The array circuit region 159A located in the top part of the cell block includes a plurality of local IO lines 152A (DQ1-DQn). A plurality of transfer units 153A are connected to each local IO line in association with the plurality of column select lines provided in association with the plurality of bit lines. Each cell sub-block in the cell block inputs and outputs data to each local IO line. All the cell sub-blocks have the same configuration. Data connection is established between the local IO lines 152A (DQ1-DQn) and main IO lines 164A (IO1-IOn) via the transfer units 154A. The main IO lines are arranged to extend across the cell block, parallel with the column select lines, toward the column decoder, and electrically connected to the data amplifiers.

Referring again to FIG. 4, since a plurality of cell blocks are arranged adjacent to each other in a vertical direction in the bank A as described in FIG. 10, the column select lines extending vertically in FIG. 4 are connected to the transfer units 153A in each cell block. The main IO lines are connected to the local IO lines via the transfer units 154A in cell block.

The bank B has the same configuration as that of the bank A. Specifically, the bank B has a plurality of cell blocks, each of which consists of a plurality of cell sub-blocks. A plurality of memory cells are arranged in matrix in each cell sub-block, and a plurality of local IO lines are provided in each cell sub-block. Further, the bank B has a plurality of transfer units 153B for transmitting data between bit lines and local IO lines in each cell sub-block, and transfer units 154B for transmitting data to the main IO lines extending in a direction orthogonal to the local IO lines. Row select lines are arranged to extend across the cell blocks, and column select lines are arranged parallel to the bit lines. The column select lines control the transfer units 153B to control data transmission between the bit lines and the local IO lines. Other detailed description will be omitted.

In FIG. 4, a bank circuit A is formed by the bank A, a row decoder 110A disposed on the right side adjacent to the bank A, a column decoder 120A disposed on the lower side adjacent to the bank A, and so on. Likewise, a bank circuit B is formed by the bank B, a row decoderd 110B disposed on the right side, a column decoder 120B disposed under the bank B, and so on. The bank A and the bank B are arranged in a lateral direction while their column decoders 130A and 130B are arranged adjacent to each other in a lateral direction. In the bank pair shown in FIG. 4, the internal terminals of the bank A and the bank B are arranged adjacent to the arrangement of the data amplifiers of the bank B. In this bank pair, therefore, the internal terminals used in common by the banks A and B are arranged on the side closer to the center of the memory chip.

FIG. 5 shows a layout of a bank pair consisting of the bank C and the bank D adjacent to each other in FIG. 1.

The combination of the banks C and D is different from the combination of the banks A and B in the wiring layout of the main IO lines. This is because microfabrication is required to form memory cells including row select lines and column select lines in a memory chip, and hence the memory cells must be formed in the same direction in all the banks, since if there are any memory cells arranged in different directions, the control of fabrication process becomes difficult.

In FIG. 1A, the bank A and the bank B are arranged in a lateral direction, while the bank C and the bank D are arranged in a vertical direction.

Therefore, if all these banks are formed in the same layout, the formation directions of the memory cells and the wiring directions of the row select lines and column select lines will differ among the banks.

Therefore, the difference in layout between FIG. 4 and FIG. 5 is necessary for enabling the memory cells and the row select lines and column select lines to be formed in the same directions among the banks. The data amplifiers and the internal signal/data terminals are disposed at different positions according to different layouts, such as adjacent to the row decoder or adjacent to the column decoder.

In the bank pair 10AB, the column decoder 120A of the bank A and the column decoder 120B of the bank B are disposed to be adjacent to each other in a lateral direction. In contrast, in the bank pair 10CD in FIG. 5, the row decoder 110C of the bank C and the row decoder 110D of the bank D are disposed to be adjacent to each other in a vertical direction. This is in order to ensure that the memory cells and the row select lines and column select lines are formed in the same directions between the bank pairs. A set of data amplifiers 130C and 130D are disposed adjacent to the row decoder 110C of the bank C and the row decoder 110D of the bank D, respectively. Internal signal/data terminals 140CD are provided adjacent to the data amplifier 130C of the bank C. On the other hand, the data amplifier 130D of the bank D is connected to internal terminals disposed at a position adjacent to the data amplifier 130C of the bank C through a bus.

Since the data amplifier 130C(D) is disposed adjacent to the row decoder in this manner, second main IO lines 165C(D) for connecting the main IO lines 164C(D) (hereafter, referred to as the first main IO lines) to the data amplifier 130(D) are disposed in a number corresponding to the number of the first main IO lines so as to extend in a direction orthogonal to the first main IO lines. The other features of the banks C and D are the same as those of the banks A and B, and description thereof will be omitted.

In the bank pair 10CD shown in FIG. 5, the internal terminals disposed in a place where the bank C is located correspond to the left side of the rectangular internal terminal region of the memory chip shown in FIG. 1A.

Referring again to FIG. 1A, the bank pair consisting of the banks A′ and B′ is arranged point-symmetrically to the bank pair of the banks A and B with respect to the center of the memory chip in FIG. 1A. In other words, a layout obtained by rotating the layout of FIG. 4 through 180 degrees around the center of the chip layout is used as the memory bank pair A′B′. Likewise, the bank pair consisting of the banks C′D′ is arranged point-symmetrically to the bank pair of the banks C and D with respect to the center of the memory chip in FIG. 1A. In other words, a layout obtained by rotating the layout of FIG. 4 through 180 degrees around the center of the chip layout is used as the memory bank pair C′D′.

### Second Exemplary Embodiment

A memory chip layout according to a second embodiment is the same as that shown in FIG. 1A. However, the arrangement of bank pairs for realizing this layout is different in the second embodiment from that in the first embodiment.

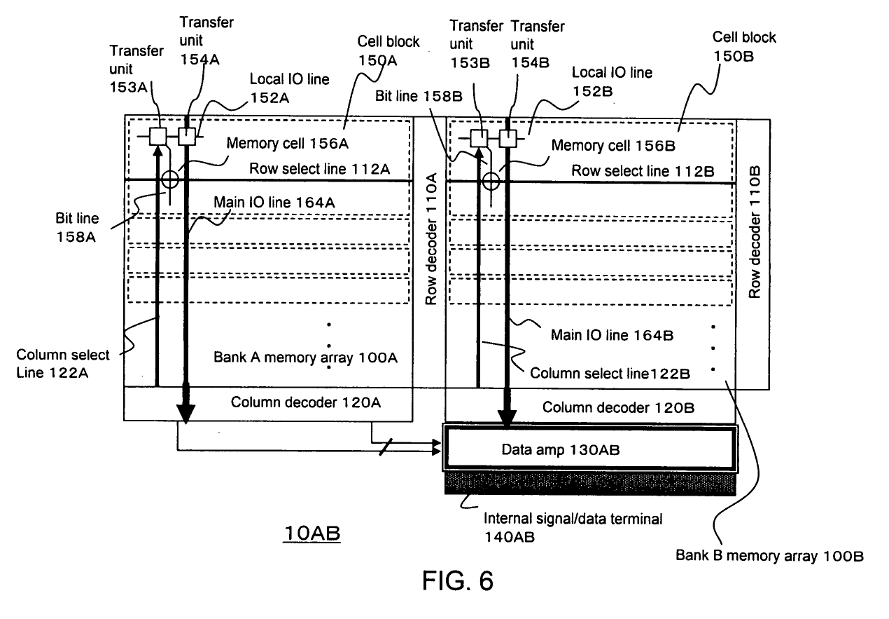

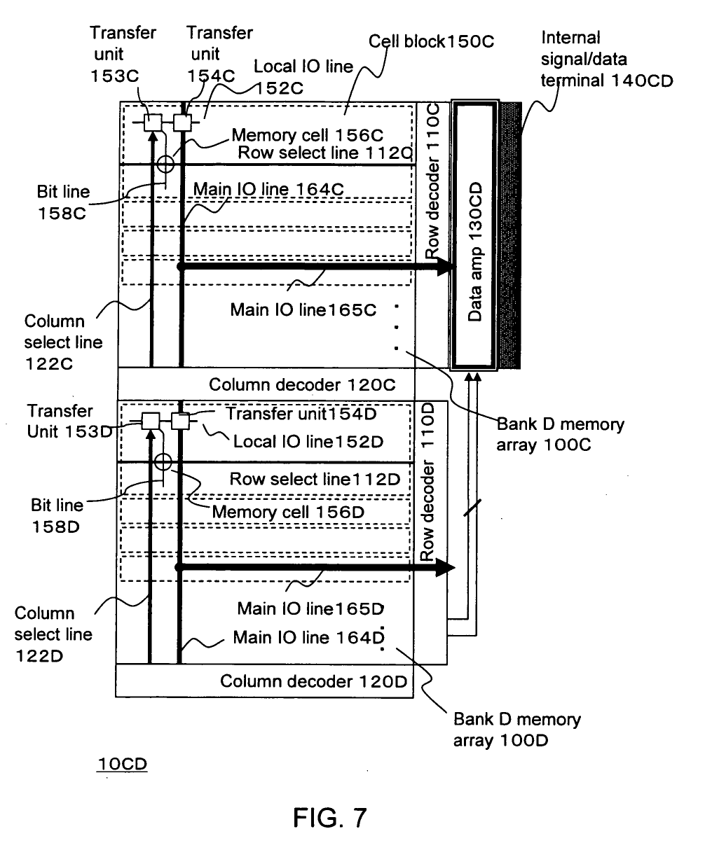

FIGS. 6 and 7 show layouts of bank pairs used in the second embodiment for realizing the layout of the memory chip shown in FIG. 1A.

FIG. 6 shows a layout of a bank pair consisting of a bank A and a bank B. This layout is different from that of the first embodiment in that, firstly, there is no data amplifier which is disposed adjacent to the lower part of the bank A in the first embodiment, and a data amplifier 130AB disposed adjacent to the lower part of the bank B is shared by both the banks A and B. Secondly, IO buses for connecting this data amplifier 130AB to main IO lines 164A are disposed outside the column decoder 120A parallel to the direction in which the column decoders are arranged. Thirdly, internal signal/data terminals 140AB are provided under the data amplifier 130AB used in common. Thus, the shared use of the data amplifiers makes it possible to reduce the number of amplifiers to a half and to reduce the area by that much. Since the IO buses are disposed to pass outside the column decoder, this example is particularly effective in the case in which the number of IO lines is small enough that the concentration of the IO lines will not cause a problem. Since the other features are the same as FIG. 4, description thereof will be omitted.

FIG. 7 shows a layout of a bank pair consisting of a bank C and a bank D according to the second embodiment.

The differences between the layout shown in FIG. 7 and the layout shown in FIG. 6 come from the necessity to ensure that the memory cells and the row select lines and column select lines are formed in the same directions among the banks.

The second embodiment is different from the first embodiment shown in FIG. 5 in that, firstly, there is no data amplifier which is disposed adjacent to the right side of the bank C in the first embodiment and, instead, a data amplifier 130CD disposed adjacent to the right side of the bank D is used for amplification of both the bank circuits C and D. Secondly, IO buses for connecting this data amplifier to main IO lines 165D are disposed to extend outside a row encoder 110D, parallel to the direction in which the row decoders are arranged. Thirdly, internal signal/data terminals 140CD are provided on the right side of the data amplifier 130CD used in common. Thus, the shared use of the data amplifiers makes it possible to reduce the number of amplifiers to a half and to reduce the area by that much. Since the IO buses are disposed to pass outside the row decoder, this example is particularly effective in the case in which the number of IO lines is small enough that the concentration of the IO lines will not cause a problem.

Referring again to FIG. 1A, the bank pair of the banks A′ and B′ is arranged point-symmetrically to the bank pair of the banks A and B with respect to the center of the memory chip in FIG. 1A. In other words, a layout obtained by rotating the layout of FIG. 6 through 180 degrees around the center of the chip layout is used as the memory bank pair A′B′.

Likewise, the bank pair consisting the banks C′ and D′ is arranged point-symmetrically to the bank pair of the banks C and D with respect to the center of the memory chip in FIG. 6. In other words, a layout obtained by rotating the layout of FIG. 6 through 180 degrees around the center of the layout of the memory chip is used as the memory bank pair C′D′.

### Third Exemplary Embodiment

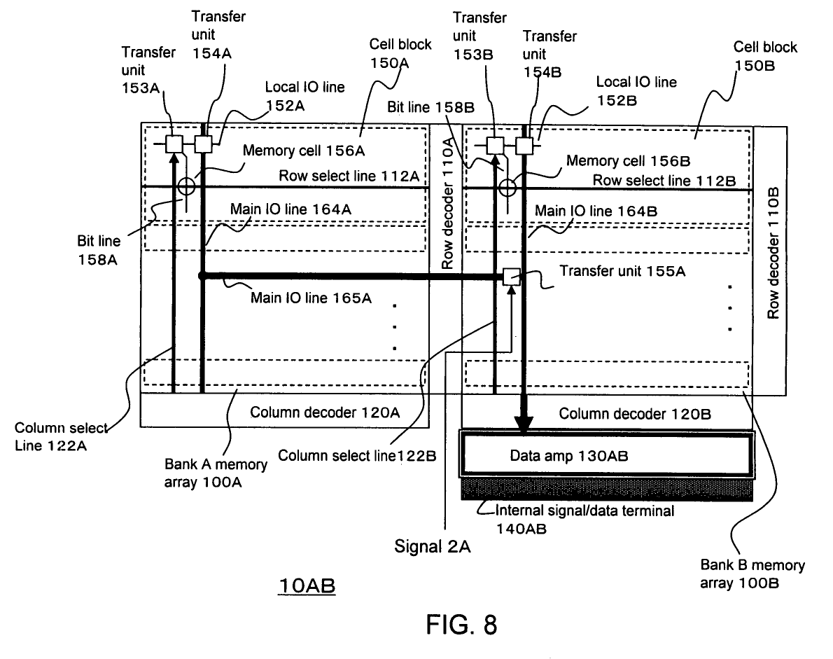

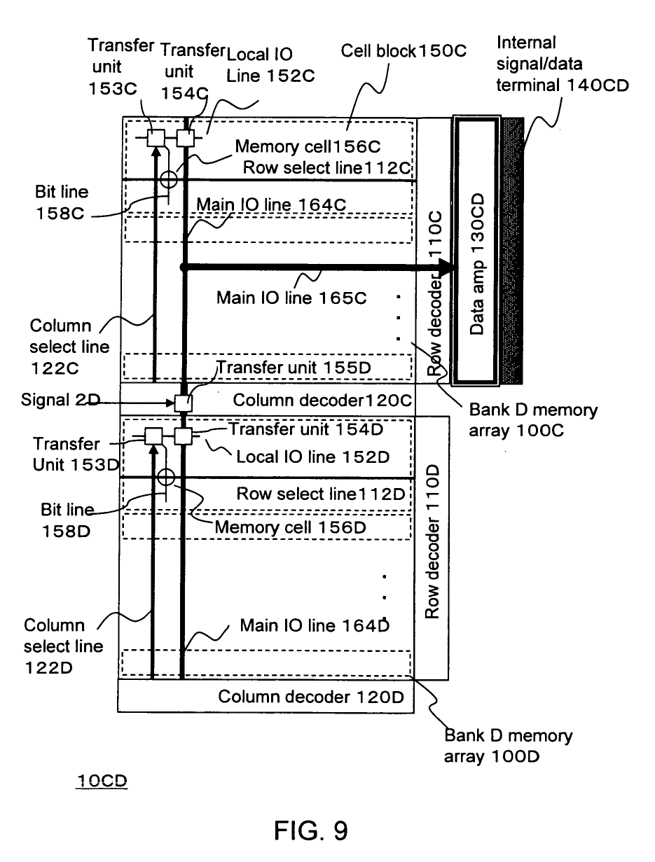

A memory chip layout according to a third embodiment of this invention is the same as the one shown in FIG. 1A. However, the arrangement of bank pairs for realizing this layout is different from the other embodiments described above. The layout of the third embodiment is particularly effective in the case in which the number of IO lines is relatively large. Description will be made with reference to FIGS. 8 and 9.

The bank pair shown in FIG. 8 shares common features with the bank pair of the second embodiment in that the bank pair of banks A and B shares a data amplifier (read/write amplifier), and internal terminals 140AB are provided 5 only under the data amplifier 10AB. The layout shown in FIG. 8 is different from the one shown in FIG. 1A in that, firstly, no bus is disposed under the column decoder 120A of the bank A to be connected to the data amplifier 130AB. A second difference in that a main IO line 164A of the bank A and a main IO line 164B of the bank B are connected to each other through a second main IO line 165A disposed above the bank A, so that the data is input to and output from the bank A via the main IO line 164B of the bank B. This means that the main IO line of the bank B is shared by the banks A and B. This makes it possible to avoid the concentration of a large number of IO lines (for example, as many as 256 or 512 IO lines) at the connection point between the main IO lines and the internal data terminals.

The second difference will be described in more detail. As shown in FIG. 8, the bank A and the bank B respectively have main IO lines 164A and 164B disposed parallel to each other, and a second main IO line 165A is disposed to connect these main IO lines 164A and 164B in a direction orthogonal thereto. The main IO line of the bank B is connected to the second main IO line via a transfer unit 155A. This transfer unit 155A is controlled by a signal 2(A). Specifically, when the main IO line 164B of the bank B is used for inputting or outputting data to or from the bank B, the transfer unit 155A blocks the transmission to the main IO lines 165A and 164A of the bank A. In contrast, when the main IO line 164B of the bank B is used as the main IO line for the bank A, the transfer unit 155A allows the data transmission. Like the transfer units 153A(B) and 154A(B), the transfer unit 155A may be formed by a transfer gate or an amplifier circuit. The other features are the same as those in FIG. 6 according to the second embodiment, and description thereof will be omitted.

FIG. 9 shows a layout of a bank pair consisting of a bank C and a bank D used in the third embodiment.

The differences between the layouts shown in FIGS. 8 and 9 come from the necessity to ensure that the memory cells and the row select lines and column select lines are formed in the same directions among the banks.

The bank pair shown in FIG. 8 shares common features with the bank pair CD of the second embodiment in that the bank pair of banks C and D shares a data amplifier 130CD, and internal terminals 140CD are provided only on the right side of the data amplifier.

The bank pair CD of FIG. 9 differs from the bank pair CD of the second embodiment in that, firstly, no bus is disposed, which is to be connected to the data amplifier 130CD from the right side of the row decoder 110D of the bank D. A second difference resides in that, instead of providing a second main IO line for the bank D, a main IO line 164C of the bank C and a main IO line 164D of the bank D are mutually connected via a transfer unit 155D, so that data is input to or output from the bank D via the main IO line 164C of the bank C and a second IO line 165C of the bank C. This means that the main IO line 164C and the second main IO line 165C of the bank C are shared by the banks C and D. This makes it possible to avoid the concentration of a large number of IO lines (for example, as many as 256 or 512 IO lines) at the connection point between the main IO lines and the internal data terminals.

The second difference will be described in more detail. As shown in FIG. 9, the main IO lines 164C and 164D of the bank C and the bank D are disposed in the same direction and mutually connected via the transfer unit 155D. This transfer unit 155D is controlled by a signal 2D. Specifically, when the main IO line 164 and second main IO line 165C of the bank C are used for inputting or outputting data to or from the bank C, the transfer unit 155D is made non-conductive to block the transmission to the main IO line 164D of the bank D. When the main IO line 164C and second main IO line 165C of the bank C are used for inputting or outputting data to or from the main IO line 164D of the bank D, the transfer unit 155D is controlled to transmit data. Like the transfer units 153C and 154C, the transfer unit 155D may be formed by a transfer gate or an amplifier circuit. The other features are the same as those in FIG. 7 according to the second embodiment, and description thereof will be omitted.

Referring again to FIG. 1A, the bank pair of the banks A′ and B′ is arranged point-symmetrically to the bank pair of the banks A and B with respect to the center of the memory chip in FIG. 1A. In other words, a layout obtained by rotating the layout of FIG. 8 through 180 degrees around the center of the chip layout is used as the memory bank pair AB′.

Likewise, the bank pair of the banks C′ and D′ is arranged point-symmetrically to the bank pair of the banks C and D with respect to the center of the memory chip in FIG. 1A. In other words, a layout obtained by rotating the layout of FIG. 9 through 180 degrees around the center of the chip layout is used as the memory bank pair C′D′.

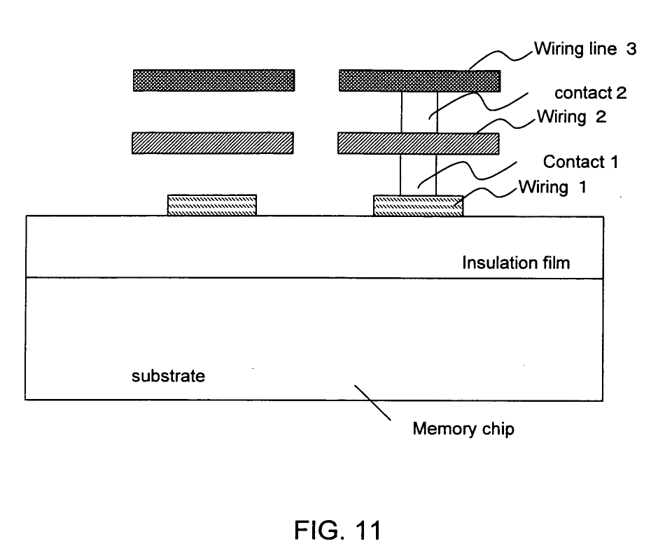

FIG. 11 is a cross-sectional view of a chip according to the third embodiment, illustrating the positional relationship of wiring lines. The column select lines, the row select lines, the local IO lines, the main IO lines, and the second main IO lines are formed by means of wiring lines 1, 2, and 3 in FIG. 11. It may be determined which wiring lines in which layers are to be used for which select lines or IO lines, depending on specific configuration of the memory array.

Description will be made of operation of a semiconductor device in which memory chips using the bank pairs of the third embodiment are employed. For the sake of convenience, the description will be made only of operation to read data from memory cells in the bank A and the bank B, instead of the entire memory chip.

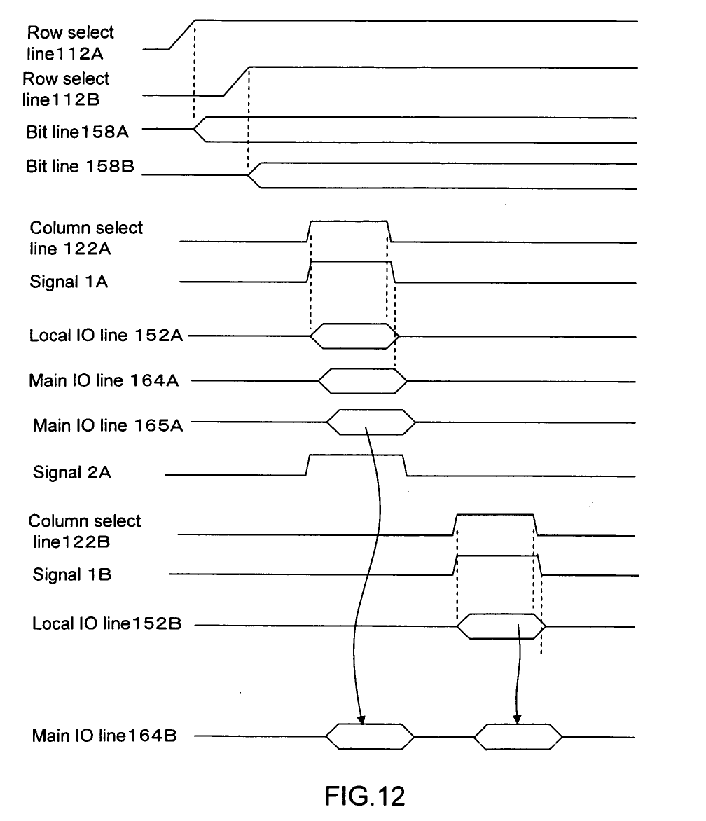

FIG. 12 shows waveforms of the operation to read data from the memory cells in the semiconductor device.

Referring to FIGS. 8 and 12, description will be made an example of 5 operation in which he row select lines of the bank A and of the bank B are sequentially selected by a row select command to activate these row select lines, and then data from the memory cells in the bank A and bank B are sequentially read out. The signal 1A is a signal for operating the transfer unit 154A, while the signal 2A is a signal for operating the transfer unit 155A.

The row select lines are activated in the first place. Upon receiving a row select command for the bank A and a row select command for the bank B, the row select lines 11 2A and 11 2B corresponding to row select addresses input simultaneously with the select command are selected. When the row select lines becomes high level, information in the memory cells 156A and 156B are read onto the bit lines 158A and 158B at the same time therewith.

Description will first be made of operational waveforms observed when a read operation is performed on the bank A. Upon receiving a read command for the bank A, a column select line 122A corresponding to a column select address which is input together with the read command is selected. At the same time as when the column select line 122A becomes high level, information on the bit line 158A is transmitted to the local IO line 152A via the transfer unit 153A. The signal 1A is a one-shot signal occurring at substantially the same timing as the column select line 122A, and information on the local IO line 152A is transmitted to the main IO line 164A via the transfer unit 154A, and further transmitted to the second main IO line 165A connected to the main IO line 164A.

While the description so far has been made of the operation performed on the memory array of the bank A, the operation then uses the transfer unit 155A on the memory array of the bank B. A signal 2A is a one-shot signal occurring at substantially the same timing as the signal 1A, and information on the main IO line 165A is transmitted to the shared main IO line 164B via the transfer unit 155A and output to the data amplifier.

Next, description will be made of a case in which a read operation is performed on the bank B. Upon receiving a read command for the bank B, a column select line 122B corresponding to a column select address which is input together with the read command is selected. At the same time as when the column select line 122B becomes high level, information on the bit line 158B is transmitted to the local IO line 152B via the transfer unit 153B. A signal 1B is a one-shot signal occurring at substantially the same timing as the column select line 122B, and information on the local IO line 152B is transmitted to the main IO line 164B via the transfer unit 154B. Since the bank B is under operation, the signal 2A will not become high level but remains low level. This means that the main IO line 165A is in the non-conductive state. Therefore, the information on the main IO line 164B is output directly to the data amplifier.

### Fourth Exemplary Embodiment

A fourth embodiment of this invention will be described.

FIG. 1B shows a plan view of a memory chip according to a fourth embodiment of this invention, in which internal signal/data terminals are disposed in a central part of the memory chip. In FIG. 1B, a rectangular region in the central pat is an internal terminal memory chip region. A bank pair of a bank A and a bank B is disposed on the left side of a region located upper than the internal terminal region. A bank pair of a bank B″ and a bank A″ is disposed on the right side of this upper region. A bank pair of banks A′″ and B′″ and a bank pair of banks B′ and A′ are respectively disposed on the left side and right side of a region lower than the internal terminal region.

In the fourth embodiment as well, the internal signal/data terminals are disposed in the central part of the memory chip and power supply terminals are disposed to extend from the central part toward the periphery of the memory chip.

As for the bank pair of the banks A and B, the configurations shown in the FIGS. 4, 6, and 8 or the configurations shown in the FIGS. 5, 7, and 9 used in the first, second and third embodiments may be used according to specific wiring configuration thereof.

The bank pair of the banks A′ and B′ is arranged point-symmetrically to the bank pair of the banks A and B with respect to the center of the chip layout in FIG. 1B. The bank pair of the banks A″ and B″ is arranged line-symmetrically to the bank pair of the banks A and B with respect to the center line running longitudinally in the memory chip. The bank pair of the banks A′″ and B′″ is positioned to be line-symmetrically to the bank pair of the banks A and B with respect to the center line running transversely in the memory chip. Such arrangement of the bank pairs is necessary for ensuring that the memory cells, and the row select lines and column select lines are formed in the same direction among the banks. As described above, one of each bank pair is provided with internal terminals, and these internal terminals are concentrated in the central internal terminal region, whereby the internal terminals of the memory cells can be concentrated in the center.

### Fifth Exemplary Embodiment

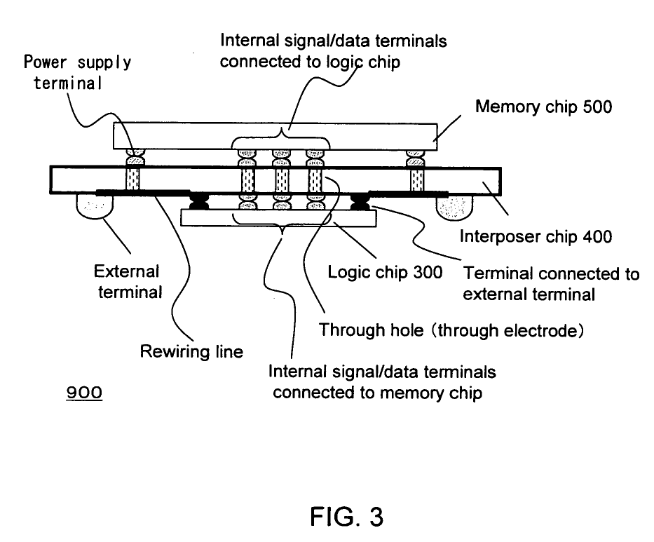

Next, a stacked semiconductor device according to this invention will be described as a fifth embodiment with reference to FIG. 3.

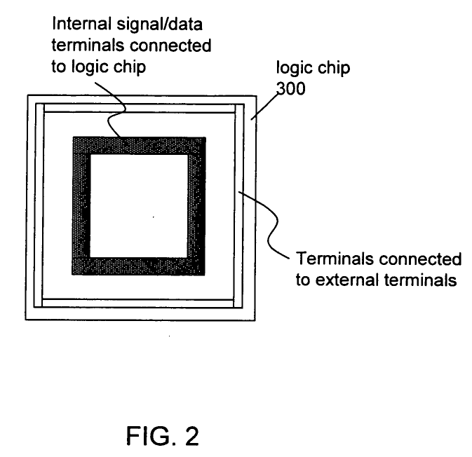

FIG. 3 is a schematic cross-sectional view of a stacked semiconductor device. As shown in FIG. 3, a logic chip 300 is disposed below an interposer chip 400, and a memory chip 500 of this invention is disposed above the interposer chip 400. The logic chip shown in FIG. 2 is used as the logic chip 300. Therefore, internal signal/data terminals to be connected to the memory chip are provided in a central part of the logic chip. External terminals connecting terminals to be connected to external terminals are provided on the logic chip in the vicinity of the outer periphery thereof. The memory chip shown in FIG. 1A or FIG. 1B is used as the memory chip 500. This means that the internal terminals of the memory chip are disposed in a central part thereof, while power supply terminals are disposed on the memory chip in the vicinity of the periphery thereof. The interposer 400 connects between the internal terminals of the logic chip and the internal terminals of the memory chip via the through holes (through electrodes) thereof. The external terminal connecting terminals of the logic chip are connected to external terminals via rewiring lines on the interposer. The power supply terminals of the memory chip are connected to the external terminal by way of the through holes (through electrodes) of the interposer.

Since the memory chip of this invention has its internal data terminals disposed only in a central part thereof, the configuration of the rewiring lines on the interposer chip in the stacked semiconductor device can be simplified. Further, the shared use of the data amplifiers and some of the main IO lines between adjacent banks makes it possible to provide a semiconductor memory in which the increase of the chip size is prevented even if a large number of IO lines are included.

While the invention has been particularly shown and described in terms of preferred embodiments thereof, it should be understood that the invention is not limited to these embodiments but may be variously embodied without departing from the spirit and scope of the invention.

What is claimed is:

1. A memory chip comprising:
internal terminals arranged in a central portion of the memory chip, the internal terminals transmitting a data signal; and
memory cell arrays arranged in a peripheral portion surrounding the central portion and electrically connected to the internal terminals.

2. The memory chip as claimed in claim 1, wherein the internal terminals are arranged to form four sides of a substantially rectangular shape.

3. The memory chip as claimed in claim 2, wherein:
the internal terminals comprises a first row of internal terminals extending in a first direction and a second row of internal terminals adjacent to the first row of internal terminals extending in a second direction orthogonal to the first direction, the first row of internal terminals and the second row of internal terminals defining two sides of the substantially rectangular shape;
the memory cell arrays comprises a first pair of memory cell arrays including a first memory cell array adjacent to the first row of internal terminals in the first direction, and a second memory cell array adjacent to the first memory cell array in the second direction, and a second pair of memory cell arrays including a third memory cell array adjacent to the second row of internal terminals in the second direction, and a fourth memory cell array adjacent to the third memory cell array in the first direction;
the second memory cell array and the third memory cell array are adjacent to each other in the first direction; and
the first pair of memory cell arrays includes a first data amplifier between the first pair of memory cell arrays and the first row of internal terminals, and the second pair of memory cell arrays includes a second data amplifier between the second pair of memory cell arrays and the second row of internal terminals.

4. The memory chip as claimed in claim 3, wherein the first data amplifier is used in common for the first and second memory cell arrays and the second data amplifier is used in common for the third and fourth memory cell arrays.

5. The memory chip as claimed in claim 3, comprising a third pair of memory cell arrays arranged point-symmetrically to the first pair of memory cell arrays with respect to the center of a memory chip layout and having the same configuration as that of the first memory cell array, and a fourth pair of memory cell arrays arranged point-symmetrically to the second pair of memory cell arrays with respect to the center of the memory chip layout and having the same configuration as that of the second pair of memory cell arrays.

6. The memory chip as claimed in claim 3, wherein:
each of the first memory cell array and the second memory cell array includes a local IO line to which a digit line selected by a column select line is connected via a first transfer unit, and a main IO line laid in the second direction and to which the local IO line is connected via a second transfer unit.

7. The memory chip as claimed in claim 3, wherein:
each of the first memory cell array and the second memory cell array includes a local IO line to which a digit line selected by a column select line is connected via a first transfer unit, a first main IO line laid in the second direction and to which the local IO line is connected via a second transfer unit;
the first main IO line of the first memory cell array is used in common by the first memory cell array and the second memory cell array to input and output data; and
the first main IO line of the first memory cell array is used in common by the first memory cell array and the second memory cell array to input and output data.

8. The memory chip as claimed in claim 1, wherein the internal terminals are arranged to form a substantially rectangular shape.

9. The memory chip as claimed in claim 8, wherein:
the internal terminals comprise first to fourth rows of internal terminals arranged in matrix;
the memory cell arrays comprise a first pair of memory cell arrays including a first memory cell array located adjacent to the first row of internal terminals in a first direction and a second memory cell array located adjacent to the first memory cell array in a second direction orthogonal to the first direction, a second pair of memory cell arrays arranged point-symmetrically to the first pair of memory cell arrays with respect to the center of a memory cell layout and having the same configuration as the first pair of memory cell arrays, a third pair of memory cell arrays arranged symmetrically to the first pair of memory cell arrays with respect to a first center line extending in the first direction passing the center of the layout, and having the same configuration as the first pair of memory cell arrays, and a fourth pair of memory cell arrays arranged symmetrically to the first pair of memory cell arrays with respect to a second center line extending in the second direction passing the center of the layout, and having the same configuration as the first pair of memory cell arrays.

10. The memory chip as claimed in claim 9, wherein the first pair of memory cell arrays has a data amplifier between the first pair of memory cell arrays and the first row of internal terminals.

11. The memory chip as claimed in claim 10, wherein the data amplifier is used in common by the first and second memory cell arrays.

12. A semiconductor device comprising:
a logic chip; and
a memory chip that is different from the logic chip, the memory chip including internal terminals arranged in a central portion of the memory chip, the internal terminals transmitting a data signal with the logic chip and memory cell arrays arranged in a peripheral portion surrounding the central portion and electrically connected to the internal terminals.

13. The semiconductor device as claimed in claim 12, wherein the internal terminals are arranged to form four sides of a substantially rectangular shape.

14. The semiconductor device as claimed in claim 13, wherein:
the internal terminals comprises a first row of internal terminals extending in a first direction and a second row of internal terminals adjacent to the first row of internal terminals extending in a second direction orthogonal to the first direction, the first row of internal terminals and the second row of internal terminals defining two sides of the substantially rectangular shape;
the memory cell arrays comprises a first pair of memory cell arrays including a first memory cell array adjacent to the first row of internal terminals in the first direction, and a second memory cell array adjacent to the first memory cell array in the second direction, and a second pair of memory cell arrays including a third memory cell array adjacent to the second row of internal terminals in the second direction, and a fourth memory cell array adjacent to the third memory cell array in the first direction;
the second memory cell array and the third memory cell array are adjacent to each other in the first direction; and
the first pair of memory cell arrays includes a first data amplifier between the first pair of memory cell arrays and the first row of internal terminals, and the second pair of memory cell arrays includes a second data amplifier between the second pair of memory cell arrays and the second row of internal terminals.

15. The semiconductor device as claimed in claim 14, wherein the first data amplifier is used in common for the first and second memory cell arrays and the second data amplifier is used in common for the third and fourth memory cell arrays.

16. The semiconductor device as claimed in claim 14, further comprising a third pair of memory cell arrays arranged point-symmetrically to the first pair of memory cell arrays with respect to the center of a memory chip layout and having the same configuration as the first memory cell array, and a fourth pair of memory cell arrays arranged point-symmetrically to the second pair of memory cell arrays with respect to the center of the memory chip layout and having the same configuration as the second pair of memory cell arrays.

17. The semiconductor device as claimed in claim 15, wherein: each of the first memory cell array and the second memory cell array includes a local IO line to which a digit line selected by a column select line is connected via a first transfer unit, and a main IO line laid in the second direction and to which the local IO line is connected via a second transfer unit.

18. The semiconductor device as claimed in claim 14, wherein:
each of the first memory cell array and the second memory cell array includes a local IO line to which a digit line selected by a column select line is connected via a first transfer unit, a first main IO line laid in the second direction and to which the local IO line is connected via a second transfer unit;
the first main IO line of the first memory cell array and the first main IO line of the second memory cell array are connected by a second main IO line laid in the first direction via a third transfer unit; and
the first main IO line of the first memory cell array is used in common for the first memory cell array and the second memory cell array to input and output data.

19. The semiconductor device as claimed in claim 12, wherein the internal terminals are arranged to form a substantially rectangular shape.

20 The semiconductor device as claimed in claim 12, wherein the memory chip and the logic chip are stacked with each other.
